(19) United States
(12) Patent Application Publication
(10) Pub. No.: US 2025/0327712 A1
(43) Pub. Date: Oct. 23, 2025

(54) LEAK DETECTION THROUGH REPURPOSED FAN TACHOMETER OUTPUT

(71) Applicant: DELL PRODUCTS L.P., Round Rock, TX (US)

(72) Inventors: Wangchun Yao, Shanghai (CN); Bingkun Chen, Shenzhen Shi (CN); Jianguo Zhang, Beijing (CN); Efan Yang, Wanhua District (TW)

(21) Appl. No.: 18/787,922

(22) Filed: Jul. 29, 2024

(30) Foreign Application Priority Data
Apr. 18, 2024 (CN) 202410471735.6

(51) Int. Cl. G01M 3/04; H05K 7/20

(52) U.S. Cl. CPC G01M 3/04; H05K 7/20272; H05K 7/20772

(57) ABSTRACT

A leak detector for detecting liquid coolant leaks includes a leak detector controller coupled to leak detection ropes. The leak detector controller associates a leak detector identifier with each of the leak detection ropes, encodes each leak detector identifier as a first pattern of square wave pulses on a first output of the leak detector controller, and encodes a rope status as a second pattern of square wave pulses on a second output of the leak detector controller.

### FIELD OF THE DISCLOSURE

This disclosure generally relates to information handling systems, and more particularly relates to detecting leaks in an information handling system through repurposed fan tachometer outputs.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A leak detector for detecting liquid coolant leaks in an information handling system may include leak detection ropes and a leak detector controller coupled to the leak detection ropes. The leak detector controller may associate a leak detector identifier with each of the leak detection ropes, encode each leak detector identifier as a first pattern of square wave pulses on a first output of the leak detector controller, and encode a rope status as a second pattern of square wave pulses on a second output of the leak detector controller.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram illustrating an information handling system according to an embodiment of the present disclosure;

FIG. 2 illustrates leak detection through repurposed fan tachometer outputs in the information handling system of FIG. 1; and

FIG. 3 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

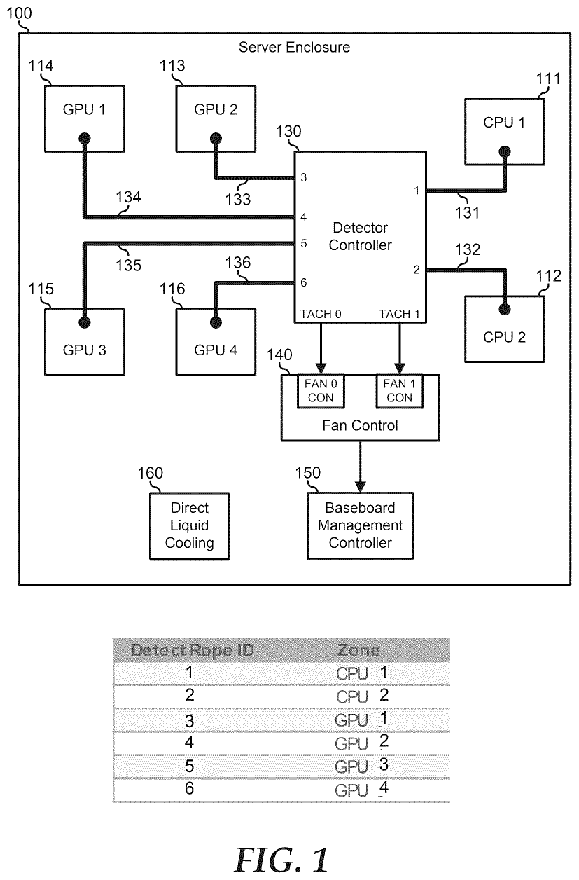

FIG. 1 illustrates an information handling system 100 that includes processors 111 and 112 (CPU 1 and CPU 2), and graphics processing units 113, 114, 115, and 116 (GPU 1, GPU 2, GPU 3, and GPU 4). Information handling system 100, and particularly CPUs 111 and 112, and GPUs 120, 122, 124, and 126 will be understood to be cooled by a direct liquid cooling (DLC) system 160. Information handling system 100 further includes a leak detector controller 130 connected to a leak detection ropes 131 (Rope 1), 132 (Rope 2), 133, (Rope 3), 134 (Rope 4), 135 (Rope 5), and 136 (Rope 6). Leak detection rope 131 detects coolant leaks proximate to CPU 111 (CPU 1), leak detection rope 132 (Rope 2) detects coolant leaks proximate to CPU 112 (CPU 2), leak detection rope 133 (Rope 3) detects coolant leaks proximate to GPU 113 (GPU 1), leak detection rope 134 (Rope 4) detects coolant leaks proximate to GPU 114 (GPU 2), leak detection rope 135 (Rope 5) detects coolant leaks proximate to GPU 115 (GPU 3), and leak detection rope 136 (Rope 6) detects coolant leaks proximate to GPU 116 (GPU 4).

This mapping of leak detection ropes 131-136 to associated CPUs 111 and 112 and GPUs 113-116 is illustrated in the table shown in FIG. 1. Leak detector controller 130 provides two (2) tachometer outputs (TACH 0 and TCH 1). The tachometer outputs (TACH 0 and TACH 1) are connected to fan connectors (FAN 0 CON and FAN 1 CON) of a fan control module 140, and the fan control module is connected to a baseboard management controller (BMC) 150. The mapping of leak detection ropes as illustrated in FIG. 1 are exemplary, and other systems with other components and different numbers of leak detection ropes will have mapping tables unique to the configuration of components and leak detection ropes, as needed or desired.

Information handling systems are increasingly being cooled utilizing DLC systems to reduce the carbon footprint and energy consumption of the information handling systems. Due to the presence of a cooling liquid in proximity to sensitive electronic devices, the need for the effective detection of leaked cooling liquid within the enclosure of the information handling system is critical. Current liquid detection systems may utilize one or more leak detection rope that operates to complete a circuit when the leak detection rope is wet. In information handling systems, such as server systems or the like, the effective detection of leaked cooling liquid typically necessitates the deployment of multiple leak detection ropes. For example a typical server may include between two (2) and four (4) CPUs and between four (4) and eight (8) GPUs, necessitating the deployment of between six (6) and twelve (12) leak detection ropes. The deployment of such a large number of leak detection ropes typically necessitates the inclusion of a similar number of connectors, one for each leak detection rope. However, the inclusion of so many connectors on the motherboard of the typical server represents an inefficient use of the real estate on the surface of the motherboard.

It has been understood by the inventors of the current disclosure that many information handling systems, and particularly the main boards or other auxiliary circuit boards within the information handling system may retain cooling fan connectors to accommodate cooling fans, even where the information handling system is cooled by a DLC system. For example, an information handling system such as a server system may include multiple Molex KK Series connector headers, such as three-pin or four-pin connector headers that are provided to power fans in the information handling system. Typically, a first pin (pin-1) provides a ground contact, a second pin (pin-2) provides a power rail contact (such as +12 VDC), a third pin (pin-3) is designated to receive a tachometer (TACH) signal from the fan, and a fourth pin (pin-4) provides a pulse-width modulated (PWM) signal to drive a variable speed fan.

In a particular embodiment, leak detector controller 130 operates to encode leak status information from leak detection ropes 131-136 onto the two (2) outputs (TACH 0 and TACH 1). In particular, leak detector controller 130 encodes a rope identifier (ID) for each of leak detection ropes 131-136 as timed pattern of square wave pulses on a first of the outputs (such as TACH 0), each unique pattern being associated with a particular one of the leak detection ropes. Further, leak detector controller 130 encodes a rope status as a timed pattern of square wave pulses on a second of the outputs (such as TACH 1).

In a particular case, leak detector controller 130 utilizes the above mentioned presence of cooling fan connector headers within information handling system 100, and particularly on fan control module 140, and connects the first output (TACH 0) to the TACH pin of the first fan connector (FAN 0 CON), and connects the second output (TACH 1) to the TACH pin of the second fan connector (FAN 1 CON). In this case, the encodings on the outputs (TACH 0 and TACH 1) of leak detector controller 130 are provided as emulated fan tachometer outputs from typical cooling fans. In particular, the typical fan tachometer output is provided as a sequence of square wave pulses in a predefined duration of time (e.g., the number of pulses provided on the output per second) For example, six pulses per second may represent a fan speed of 360 revolutions per minute (RPM), which may be understood to be 10% of the typical maximum fan speed of 3600 RPM, twelve pulses per second may represent a fan speed of 720 RPM, 20% of the maximum fan speed, etc. In furtherance of this case, on the first output (TACH 0) of leak detector controller 130, a fan tachometer output of 0 RPM may be associated with leak detection rope 131 (Rope 1), a fan tachometer output of 720 RPM may be associated with leak detection rope 132, and so on. Table 1, below, illustrates this encoding for the first output (TACH 0) of leak detector controller 130.

TABLE 1
TACH 1 - Rope ID Mapping

| | |
|---|---|
| TACH 1 | Rope ID |

| | | |
|---|---|---|
| 0 | RPM | Rope 1 |
| 720 | RPM | Rope 2 |
| 1440 | RPM | Rope 3 |
| 2160 | RPM | Rope 4 |
| 2880 | RPM | Rope 5 |
| 3600 | RPM | Rope 6 |

On the second output (TACH 1) of leak detector controller 130, a fan tachometer output of 0 RPM may be associated with a detection error on the associated leak detection rope, a fan tachometer output of 1800 RPM may be associated with a good leak detection rope that is detecting no leak condition, and a fan tachometer output of 3600 RPM may be associated with a good leak detection rope that is detecting a leak condition. Table 2, below, illustrates this encoding for the second output (TACH 1) of the leak detector controller.

TABLE 2
TACH 2 - Rope Statis

| TACH 2 | Status |
|---|---|
| 0 RPM | Sensor Error |
| 1800 RPM | GOOD |
| 3600 RPM | Leak Detected |

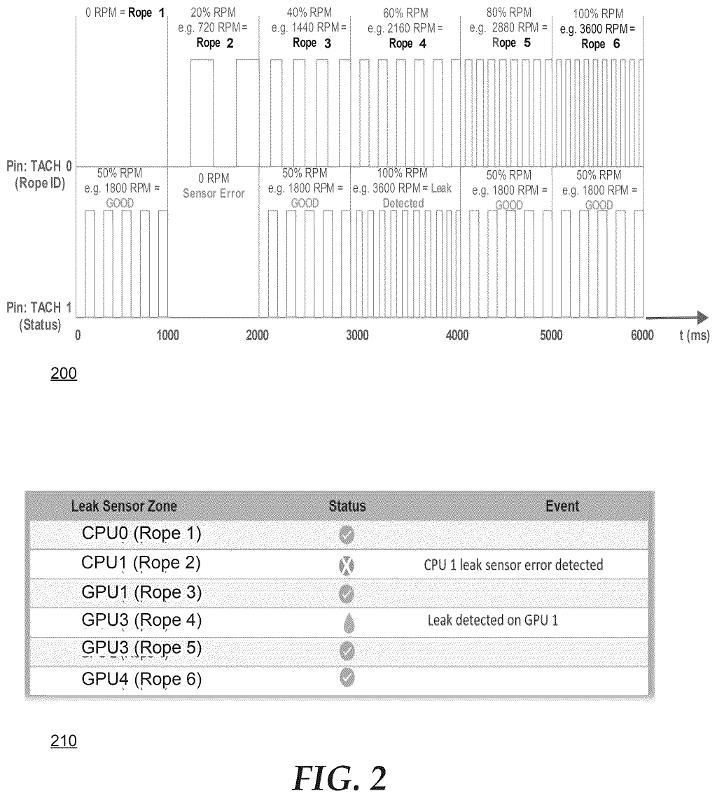

Taken in combination, leak detector controller 130 operates to provide time-sliced samples of a particular one of leak detection ropes 131-136 on the first output (TACH 0), and the status of that particular leak detection rope on the second output (TACH 1). FIG. 2 illustrates an exemplary time sequence 200 of signals on the first and second outputs of leak detector controller 130. In a first time-slice from zero to 1 second, leak detector controller 130 provides a 0 RPM output on TACH 0, indicating that leak detection rope 131 is selected, and the leak detector controller provides a 1800 RPM output on TACH 1, indicating that leak detection rope 132 is in good condition and is detecting no leak condition. In subsequent third, fifth, and sixth time slices, from 2-3, 4-5, and 5-6 seconds, leak detector controller 130 provides respective 1440, 2880, and 3600 RPM outputs on TACH 0, indicating that respective leak detection ropes 133, 135, and 136 are selected and the associated TACH 1 output for each selected leak detection rope is provided as 1800 RPM, indicating that the associated leak detection ropes are in good condition and are detecting no leak conditions.

In a second time-slice, from 1-2 seconds, leak detector controller 130 provides a 720 RPM output on TACH 0, indicating that leak detection rope 132 is selected, and the leak detection controller provides a 0 RPM output on TACH 1, indicating that leak detection rope 132 is not in good condition. In a fourth time slice, from 3-4 second, leak detector controller 130 provides a 2160 RPM output on TACH 0, indicating that leak detection rope 134 is selected, and the leak detection controller provides a 3600 RPM output on TACH 1, indicating that leak detection rope 134 is in good condition and is detecting a leak condition. A table 210 summarizes the results of time sequence 200.

Returning to FIG. 1, fan control module 140 operates to communicate the fan tachometer information from leak detector controller 130 to BMC 150. BMC 150 operates to reinterpret the fan tachometer information from fan speeds to leak detection rope status information. In particular, BMC 150 typically receives fan speed information from one or more fan in an information handling system, and operates to manage the fan speed, and other operations of information handling system 100 based upon the fan speed information. However BMC 150 operates to receive information on the same inputs as the fan speed information, but the BMC is configured to be aware that information handling system 100 is not fan-cooled, but is cooled by DLC system 160. In this case, BMC firmware is configured to reinterpret the input information as leak detection rope status information. In response, BMC 150 may be configured to take any action commensurate with the detection of a leak within information handling system 100, such as migrating workloads off of the information handling system, shutting down the information handling system, providing an indication to a management system that the information handling system is experiencing a leak, or the like.

In a particular embodiment, leak detector controller 130 provides the outputs (TACH 0 and TACH 1) directly to BMC 150. For example, the fan connector inputs (that is, the TACH pins of FAN 0 CON and FAN 1 CON) may be connected directly to BMC 150, and BMC 150 may operate to provide the functionality of fan control module 140 for information handling system 100, as needed or desired. In another example, information handling system 100 may not include fan connectors, the information handling system being designed from the outset to operate with DLC system 160 rather than with cooling fans. In this case the inputs (TACH 0 and TACH 1) from leak detector controller 130 may be provided to a logic device associated with BMC 150, such as a complex programmable logic device (CPLD), a field-programmable gate array (FPGA), or the like.

In this regard, leak detector controller 130 may be implemented as an add-in module to information handling system 100, may be implemented as logic on a printed circuit board (PCB) of the information handling system, such as a mainboard, a daughter card, or the like, may be implemented as a part of a management environment established by BMC 150, or may be otherwise implemented in hardware, firmware, or a combination thereof, as needed or desired. In a particular embodiment, leak detector controller 130 is incorporated into the logic device associated with BMC 150. In any case, the emulation of TACH signals by leak detector controller 130 simplifies the implementation of the current embodiments. In particular, the elements of hardware and firmware that are implemented to interpret fan tachometer inputs do not need to be modified, and any modifications to BMC 150 may be provided in the firmware that gives an interpretation to the physical signals from the outputs of leak detector controller 130.

As shown in FIGS. 1, 2A, and 2B, and as described above, a wide range of numbers of leak detection ropes may be designed into an information handling system, as needed or desired. In particular, where the number of leak detection ropes differs from the six (6) leak detection ropes 131-136, leak detector controller 130 may operate to ascribe the particular number of leak detection ropes to a similar number of rope IDs, and to encode that number of rope IDs proportionally across the typical tachometer range. For example, where an information handling system includes ten (10) leak detection ropes, a leak detector controller can encode the rope IDs in 400 RPM increments: 0 RPM for rope 1, 400 RPM for rope 1 . . . , and 3600 RPM for rope 10. Generally, the rope ID encodings can be given as:

$${E}_{R} = R * 3600 / ( N - 1 ) ( for R = 1 - N ) \qquad Equation 1$$

where E_{R} is the rope encoding in RPM for a particular rope (R), and N is the number of rope IDs. Then, in interpreting the fan tachometer information, a system BMC may hard code the number of leak detection ropes within the information handling system and the fan tachometer speeds associated with each leak detection rope, or the number of leak detection ropes may be provided as a setting within the BMC firmware, and the BMC may operate to implement Equation 1 to correctly interpret the fan tachometer information.

The time-based ordering of rope ID and status encodings may not necessarily be provided in rope-ID order. For example, as soon as a leak is detected by a particular leak detection rope, the associated encoded rope ID and the leak detected status can be provided, jumping other rope IDs in the rope-ID order. In this way, a minimum amount of time passes before the leak detector controller informs the BMC of a leak.

Other encoding schemes may be utilized in encoding rope IDs and fan status. For example, a binary representation of the rope IDs (such as 0h0 for rope 1, 0h2 for rope 2 . . . , and 0hA for rope 10) may be provided, or other rope ID encoding may be utilized as needed or desired. In another example, additional statuses may be encoded as needed or desired. The absence of a particular leak detection rope within the information handling system may be identified by a different status encoding than the error status, which would then be interpreted as indicating that the leak detection rope was installed but has gone bad.

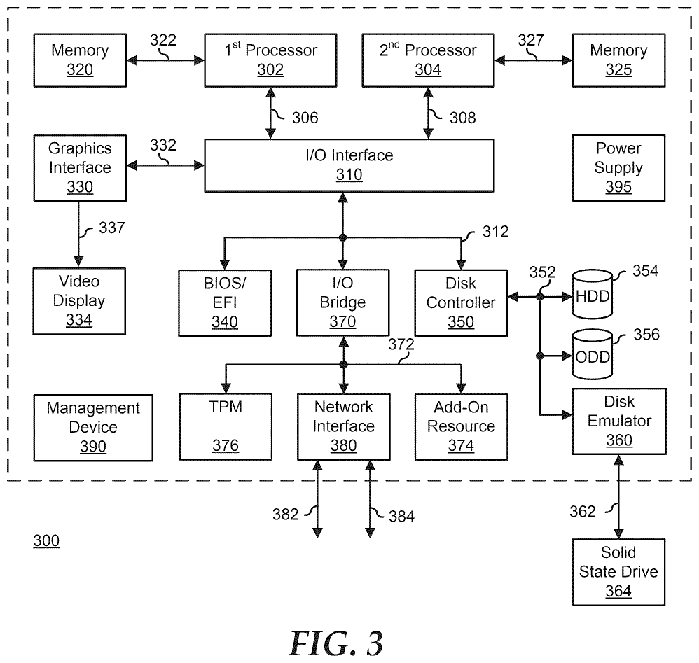

FIG. 3 illustrates a generalized embodiment of an information handling system 300 similar to information handling system 100. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 300 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 300 can include processing resources for executing machine-executable code, such as a central processing unit (CPU), a programmable logic array (PLA), an embedded device such as a System-on-a-Chip (SoC), or other control logic hardware. Information handling system 300 can also include one or more computer-readable medium for storing machine-executable code, such as software or data. Additional components of information handling system 300 can include one or more storage devices that can store machine-executable code, one or more communications ports for communicating with external devices, and various input and output (I/O) devices, such as a keyboard, a mouse, and a video display. Information handling system 300 can also include one or more buses operable to transmit information between the various hardware components.

Information handling system 300 can include devices or modules that embody one or more of the devices or modules described below, and operates to perform one or more of the methods described below. Information handling system 300 includes a processors 302 and 304, an input/output (I/O) interface 310, memories 320 and 325, a graphics interface 330, a basic input and output system/universal extensible firmware interface (BIOS/UEFI) module 340, a disk controller 350, a hard disk drive (HDD) 354, an optical disk drive (ODD) 356, a disk emulator 360 connected to an external solid state drive (SSD) 362, an I/O bridge 370, one or more add-on resources 374, a trusted platform module (TPM) 376, a network interface 380, a management device 390, and a power supply 395. Processors 302 and 304, I/O interface 310, memory 320, graphics interface 330, BIOS/UEFI module 340, disk controller 350, HDD 354, ODD 356, disk emulator 360, SSD 362, I/O bridge 370, add-on resources 374, TPM 376, and network interface 380 operate together to provide a host environment of information handling system 300 that operates to provide the data processing functionality of the information handling system. The host environment operates to execute machine-executable code, including platform BIOS/UEFI code, device firmware, operating system code, applications, programs, and the like, to perform the data processing tasks associated with information handling system 300.

In the host environment, processor 302 is connected to I/O interface 310 via processor interface 306, and processor 304 is connected to the I/O interface via processor interface 308. Memory 320 is connected to processor 302 via a memory interface 322. Memory 325 is connected to processor 304 via a memory interface 327. Graphics interface 330 is connected to I/O interface 310 via a graphics interface 332, and provides a video display output 337 to a video display 334. In a particular embodiment, information handling system 300 includes separate memories that are dedicated to each of processors 302 and 304 via separate memory interfaces. An example of memories 320 and 325 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 340, disk controller 350, and I/O bridge 370 are connected to I/O interface 310 via an I/O channel 312. An example of I/O channel 312 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 310 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 340 includes BIOS/UEFI code operable to detect resources within information handling system 300, to provide drivers for the resources, initialize the resources, and access the resources. BIOS/UEFI module 340 includes code that operates to detect resources within information handling system 300, to provide drivers for the resources, to initialize the resources, and to access the resources.

Disk controller 350 includes a disk interface 352 that connects the disk controller to HDD 354, to ODD 356, and to disk emulator 360. An example of disk interface 352 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 360 permits SSD 364 to be connected to information handling system 300 via an external interface 362. An example of external interface 362 includes a USB interface, an IEEE 1394 (Firewire) interface, a proprietary interface, or a combination thereof. Alternatively, solid-state drive 364 can be disposed within information handling system 300.

I/O bridge 370 includes a peripheral interface 372 that connects the I/O bridge to add-on resource 374, to TPM 376, and to network interface 380. Peripheral interface 372 can be the same type of interface as I/O channel 312, or can be a different type of interface. As such, I/O bridge 370 extends the capacity of I/O channel 312 where peripheral interface 372 and the I/O channel are of the same type, and the I/O bridge translates information from a format suitable to the I/O channel to a format suitable to the peripheral interface 372 where they are of a different type. Add-on resource 374 can include a data storage system, an additional graphics interface, a network interface card (NIC), a sound/video processing card, another add-on resource, or a combination thereof. Add-on resource 374 can be on a main circuit board, on separate circuit board or add-in card disposed within information handling system 300, a device that is external to the information handling system, or a combination thereof.

Network interface 380 represents a NIC disposed within information handling system 300, on a main circuit board of the information handling system, integrated onto another component such as I/O interface 310, in another suitable location, or a combination thereof. Network interface device 380 includes network channels 382 and 384 that provide interfaces to devices that are external to information handling system 300. In a particular embodiment, network channels 382 and 384 are of a different type than peripheral channel 372 and network interface 380 translates information from a format suitable to the peripheral channel to a format suitable to external devices. An example of network channels 382 and 384 includes InfiniBand channels, Fibre Channel channels, Gigabit Ethernet channels, proprietary channel architectures, or a combination thereof. Network channels 382 and 384 can be connected to external network resources (not illustrated). The network resource can include another information handling system, a data storage system, another network, a grid management system, another suitable resource, or a combination thereof.

Management device 390 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 300. In particular, management device 390 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 300, such as system cooling fans and power supplies. Management device 390 can include a network connection to an external management system, and the management device can communicate with the management system to report status information for information handling system 300, to receive BIOS/UEFI or system firmware updates, or to perform other task for managing and controlling the operation of information handling system 300. Management device 390 can operate off of a separate power plane from the components of the host environment so that the management device receives power to manage information handling system 300 where the information handling system is otherwise shut down. An example of management device 390 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 390 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A leak detector for detecting liquid coolant leaks in an information handling system, the leak detector comprising:
a plurality of leak detection ropes; and
a leak detector controller coupled to the leak detection ropes, wherein the leak detector controller is configured to associate a leak detector identifier with each of the leak detection ropes, to encode each leak detector identifier as a first pattern of square wave pulses on a first output of the leak detector controller, and to encode a rope status as a second pattern of square wave pulses on a second output of the leak detector controller.

2. The leak detector of claim 1, wherein the leak detector controller is further configured to determine the rope status for each of the leak detection ropes.

3. The leak detector of claim 2, wherein the leak detector controller is further configured, at a first time, to output a first leak detector identifier associated with a first one of the leak detection ropes on the first output and to output the rope status associated with the first leak detection rope on the second output.

4. The leak detector of claim 3, wherein the leak detector controller is further configured, at a second time, to output a second leak detector identifier associated with a second one of the leak detection ropes on the first output and to output the rope status associated with the second leak detection rope on the second output.

5. The leak detector of claim 2, wherein the rope status includes a first indication that a particular one of the leak detection ropes exhibits an error condition, a second indication that the particular leak detection rope is in a good condition and is detecting no liquid coolant leak, and a third indication that the particular leak detection rope is in the good condition and is detecting the liquid coolant leak.

6. The leak detector of claim 5, wherein the first and second patterns emulate a fan tachometer output.

7. The leak detector of claim 6, wherein the first pattern (E_{R}) for a particular leak detector identifier (R) is given as E_{R}=R*3600/(N−1) in revolutions per minute for R=1 to N, where N is a total number of the leak detection ropes.

8. The leak detector of claim 6, wherein the second pattern for the first indication is a zero (0) revolutions per minute pattern.

9. The leak detector of claim 6, wherein the second pattern for the second indication is an 1800 revolutions per minute pattern.

10. The leak detector of claim 6, wherein the second pattern for the third indication is a 3600 revolutions per minute pattern.

11. A method for detecting liquid coolant leaks in an information handling system, the method comprising:
providing, in the information handling system, a plurality of leak detection ropes;
providing, in the information handling system, leak detector controller coupled to the leak detection ropes;
associating, by the leak detector controller, leak detector identifier with each of the leak detection ropes;
encoding, by the leak detector controller, each leak detector identifier as a first pattern of square wave pulses on a first output of the leak detector controller; and
encoding, by the leak detector controller, a rope status as a second pattern of square wave pulses on a second output of the leak detector controller.

12. The method of claim 11, further comprises determining, by the leak detector controller, the rope status for each of the leak detection ropes.

13. The method of claim 12, further comprising:
outputting a first leak detector identifier associated with a first one of the leak detection ropes on the first output at a first time; and
outputting the rope status associated with the first leak detection rope on the second output at the first time.

14. The method of claim 13, further comprising:
outputting a second leak detector identifier associated with a second one of the leak detection ropes on the first output at a second time; and
outputting the rope status associated with the second leak detection rope on the second output at the second time.

15. The method of claim 12, wherein the rope status includes a first indication that a particular one of the leak detection ropes exhibits an error condition, a second indication that the particular leak detection rope is in a good condition and is detecting no liquid coolant leak, and a third indication that the particular leak detection rope is in the good condition and is detecting the liquid coolant leak.

16. The method of claim 15, wherein the first and second patterns emulate a fan tachometer output.

17. The method of claim 16, wherein the first pattern (E_{R}) for a particular leak detector identifier (R) is given as E_{R}=R*3600/(N−1) in revolutions per minute for R=1 to N, where N is a total number of the leak detection ropes.

18. The method of claim 16, wherein the second pattern for the first indication is a zero (0) revolutions per minute pattern, the second pattern for the second indication is a 1800 revolutions per minute pattern, and the second pattern for the third indication is a 3600 revolutions per minute pattern.

19. An information handling system, comprising:
a baseboard management controller; and
a leak detector for detecting liquid coolant leaks in an information handling system, the leak detector including:
a plurality of leak detection ropes; and
a leak detector controller coupled to the leak detection ropes, wherein the leak detector controller is configured to associate a leak detector identifier with each of the leak detection ropes, to encode each leak detector identifier as a first pattern of square wave pulses on a first output of the leak detector controller, and to encode a rope status as a second pattern of square wave pulses on a second output of the leak detector controller.

20. The information handling system of claim 19, wherein the leak detector controller is further configured to determine the rope status for each of the leak detection ropes.
